(19) United States
(12) Patent Application Publication
(10) Pub. No.: US 2014/0000696 A1
(43) Pub. Date: Jan. 2, 2014

(54) LOW-BANDGAP RUTHENIUM-CONTAINING COMPLEXES FOR SOLUTION-PROCESSED ORGANIC SOLAR CELLS

(71) Applicant: Nano and Advanced Materials Institute Limited, Clear Water Bay (HK)

(72) Inventors: Wai-Yeung Wong, Clear Water Bay (HK); Qian Liu, Clear Water Bay (HK); Cheuk-Lam Ho, Clear Water Bay (HK)

(21) Appl. No.: 13/930,639

(22) Filed: Jun. 28, 2013

Related U.S. Application Data
(60) Provisional application No. 61/690,571, filed on Jun. 29, 2012.

(51) Int. Cl. H01L 51/42

(52) U.S. Cl. CPC H01L 51/4253; Y10S 977/74; Y10S 977/948; B82Y 99/00
USPC 136/256; 136/263; 548/103; 977/740; 977/948

(57) ABSTRACT

This invention relates to a class of ruthenium(II) bis(aryleneethynylene) complexes for use in bulk heterojunction (BHJ) solar cell devices, and the method of synthesizing thereof. This invention also relates to a BHJ solar cell device comprising the ruthenium(II) bis(aryleneethynylene) complex. The ruthenium(II) bis(aryleneethynylene) complex having the following structure:

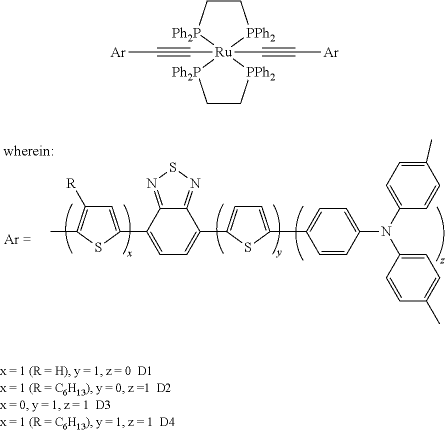

### FIELD OF THE INVENTION

This invention relates to a class of metal-containing complexes for use in solar cell devices and the method of synthesizing thereof. Particularly but not exclusively, this invention relates to a class of ruthenium-containing complexes for use in bulk heterojunction (BHJ) solar cells and the method of synthesizing thereof.

### TECHNICAL BACKGROUND OF THE INVENTION

Our society increasingly relies on the supply of coal, oil and natural gas for daily use. However, these fossil fuels are limited in supply and will be depleted some day in the future. The carbon dioxide produced from the combustion of fossil fuels results in a rapid increase of carbon dioxide concentration in the atmosphere which consequently affects our climate and leads to global warming effect. Under these circumstances, as a clean, renewable and plentiful energy source, solar energy has the capacity to meet the increasing global energy needs. Harvesting energy directly from sunlight using photovoltaic technology significantly reduces the atmospheric emissions, preventing the environment from the detrimental effects of these gases. As a promising cost-effective alternative to silicon-based solar cells, increasing attention has been paid to organic photovoltaic cells (OPVs).

### SUMMARY OF THE INVENTION

In accordance with a first aspect of the present invention, there is provided a ruthenium-containing complex having structure of Formula (I):

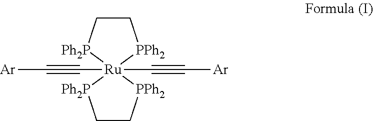

wherein Ar is selected from a group consisting of at least one benzothiadiazole group, one or no triphenylamine group, at least one thiophene group and a mixture thereof.

In an embodiment of the first aspect, Ar is with a structure of:

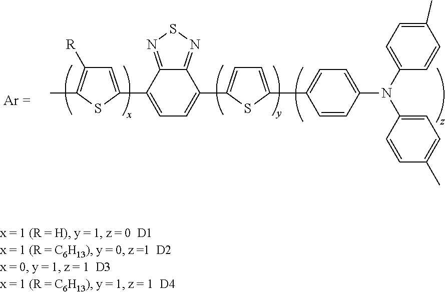

In accordance with a second aspect of the present invention, there is provided a method of preparing the ruthenium-containing complex of claim 1, comprising steps of:

(a) providing a ligand with structure of Ar—C≡CH;

(b) providing a ruthenium-containing compound;

(c) reacting the ligand with the ruthenium-containing compound in a solvent to form a crude product;

(d) purifying the crude product.

In an embodiment of the second aspect, the ruthenium-containing compound comprises cis-[RuCl₂(bis(diphenylphosphino)ethane)₂].

In an embodiment of the second aspect, the solvent comprises triethylamine, dichloromethane or a mixture thereof.

In an embodiment of the second aspect, the reacting step is conducted in the presence of a catalyst.

In an embodiment of the second aspect, the catalyst comprises sodium hexafluorophosphate.

In an embodiment of the second aspect, the purifying step is conducted by column chromatography.

In accordance with a third aspect of the present invention, there is provided a bulk heterojunction solar cell device, comprising:

a hole-collection electrode;

an electron-collection electrode;
an active layer disposed between the hole-collection and electron-collection electrodes;
   wherein the active layer comprises the ruthenium-containing complex as embodied in the first aspect of the present invention.

In an embodiment of the third aspect, the active layer further comprises a fullerene derivative.

In an embodiment of the third aspect, the fullerene derivative comprises PC₇₀BM.

In an embodiment of the third aspect, the ruthenium-containing complex and the PC₇₀BM is in a weight ratio of 1:4.

In an embodiment of the third aspect, the hole-collection electrode comprises indium tin oxide with a spin-coated poly(3,4-ethylene-dioxythiophene)/poly(styrenesulphonate) layer.

In an embodiment of the third aspect, the electron-collecting electrode comprises aluminum.

### BRIEF DESCRIPTION OF THE DRAWINGS

FIG. 1 shows a schematic diagram for preparing ligand L1 and complex D1 in accordance with an embodiment of the present invention.

FIG. 2 shows a schematic diagram for preparing ligand L2 and complex D2 in accordance with an embodiment of the present invention.

FIG. 3 shows a schematic diagram for preparing ligand L3 and complex D3 in accordance with an embodiment of the present invention.

FIG. 4 shows a schematic diagram for preparing ligand L4 and complex D4 in accordance with an embodiment of the present invention.

FIG. 5 shows the normalized absorption spectra of D1-D4 in dichloromethane (CH₂Cl₂) at 298 K.

FIG. 6 shows the normalized photoluminescence spectra of D1-D4 in CH₂Cl₂ at 298 K.

FIG. 7 shows the current-voltage (J-V) curves of BHJ devices with D1/PC₇₀BM (1:4) as the active layer under simulated AM1.5 solar light illumination in accordance with an embodiment of the present invention.

### DETAILED DESCRIPTION OF THE PREFERRED EMBODIMENTS

Without wishing to be bound by theory, the inventor through trials, research, study and review of results and observations is of the opinion that the application of ruthenium-containing complex for bulk heterojunction (BHJ) solar cells has beneficial effects. BHJ solar cells comprising a donor-acceptor (D-A) system of electron-donating conjugated polymers and electron-withdrawing fullerene derivatives have led to improvements in the power conversion efficiencies (PCEs). To date, many fullerene derivatives have been investigated, such as the most commonly used [6,6]-phenyl-C₆₁-butyric acid methyl ester (PCBM) and the C₇₀ analogue of PCBM, [6,6]-phenyl-C₇₁-butyric acid methyl ester (PC₇₀BM). Moreover, the use of numerous π-conjugated polymers as donor materials, including organic polymers based on phthalocyanines, thiophene and/or arylacetylenes, and metal-containing derivatives such as platinum(II) polyynes, allows the fabrication of efficient BHJ devices. The structure and absorption spectra of these organic molecules can be easily modulated to suit a particular application. At present, the PCE has shown values in excess of 8-9% based on the polymer-based BHJ solar cells under simulated AM1.5 solar illumination (He et al., Nat. Photon., 2012, 6, 591; He et al., Adv. Mater., 2011, 23, 4636). In the case of device fabrication, the primary thin film preparation methods typically include high vacuum vapor deposition of thermally stable molecules and solution processing of soluble organic materials. The solution processing approach is more cost-efficient as compared to the vacuum-based vapor deposition, and can also enhance the efficiency of material consumption, simplify the production process and reduce the size and/or cost of the manufacturing unit. Although the polymers used in the BHJ solar cells have shown great promise in the improvement of the absorption and film processing abilities, the molecular weight issue and purification of these polymers, which can severely influence the reproducibility of the device performance, still pose a big problem to the researchers in this field. In particular, the Hagihara-type polycondensation usually gives polymers of large molecular weight distribution with polydispersity of 2 and undefined end groups. The amorphous nature of these polymers will also result in lower charge carrier mobilities. Recently, the solution-processed small-molecule BHJ solar cells have attracted much attention because small molecules are easier to synthesize and purify, and possess well-defined molecular structures and definite molecular weight and high purity without batch to batch variations, which are different from the polymeric systems that intrinsically display large structural variations in molecular weight, polydispersity and regioregularity. To date, PCEs have evolved from <1% to a recent value of up to 7.1% (Zhou et al., J. Am. Chem. Soc., 2012, 134, 16345).

Therefore, the judicious design and synthesis of new molecular donor materials for improving the energy conversion efficiency of these BHJ devices is still a great challenge. However, to our knowledge, related work using organometallic molecular compounds is yet very scarce in the literature.

Recently, we and others have demonstrated a number of efficient BHJ solar cells based on platinum-containing polyynes. While the charge transport in platinum(II) acetylides has been demonstrated, solution-processable organometallic polymer semiconductors possessing the D-A architecture and platinum center in the backbone were recently shown to exhibit broad absorption bands due to the intramolecular charge transfer (ICT) between the D and A units and small bandgaps (even down to the near-infrared region) suitable for photovoltaic devices. The complexation of an electron-rich platinum(II) ion into the conjugated chain was reported to enhance the intrachain charge transport of i-conjugated polymers. In 2007, our research group has succeeded in developing a soluble low-bandgap platinum(II) metallopolyyne containing 4,7-di-2′-thienyl-2,1,3-benzothiadiazole suitable for the OPV application. The BHJ solar cells consisting of this metallated polymer and PCBM (1:4 blend ratio) exhibited a high PCE of 4.1±0.9% in spite of the simple device structure (no TiOₓ spacer layer) and no thermal annealing (Wong et al, Nature Mater., 2007, 6, 521). This is the first low-bandgap metallopolyyne that shows such high efficiency. The work has opened up a new venture towards high-efficiency polymer solar cells to capture sunlight for efficient power generation, which contrasts with the purely organic donor materials. The chemical structures of polyplatinynes and their absorption coefficients, bandgaps, charge mobilities, accessibility of triplet excitons, molecular weights and blend film morphologies, critically influence the device performance (Wong et al., Macromol. Chem. Phys., 2008, 209, 14; Wong et al., Acc. Chem. Res., 2010, 43, 1246). A series of polyplatinynes has then been developed which allows tuning of the optical absorption and charge transport properties as well as the solar cell efficiency using different number of oligothienyl rings and central aromatic units (Wong et al., J. Am. Chem. Soc., 2007, 129, 14372; Liu et al., Adv. Funct. Mater., 2008, 18, 2824). Their photovoltaic responses and PCEs depend to a large extent on the number of thienyl rings along the main chain. Although still in its infancy, the use of platinum(II) metallopolyynes and more recently, their oligomers (Wong et al., Chem. Eur. J., 2012, 18, 1502; Zhao et al., Chem. Mater., 2010, 22, 2325) represents an innovative and challenging research area for the development of BHJ solar cells.

So far, the majority of the organometallic poly-yne polymers that have been prepared contains metals from the group 10 elements (i.e. the Ni, Pd and Pt triad), where the metal geometry is generally required to be square planar in the +2 oxidation state, and any redox process at the metal center usually results in a change in coordination number and geometry. The relative effectiveness of the different transition metals and the relative energies of their excited states on photovoltaic response has not been investigated in detail. We intend to prepare bis(acetylide) complexes of mononuclear Ru(II), using the standard synthetic route, and study their photophysical and photovoltaic properties.

Following the synthesis of a series of platinum(II) bis(aryleneethynylene) donor complexes by the inventors, they found that ruthenium(II) bis(acetylide) donor complexes are interesting, and these complexes are rarely used in small-molecule based solar cells (Colombo et al., Organometallics, 2011, 30, 1279; Long et al., Angew. Chem. Int. Ed., 2003, 42, 2586). The incorporation of a ruthenium metal center instead of a relatively more expensive platinum in a conjugated backbone and the presence of D-A structure in these complexes should be promising for OPV study, since a red shift of the absorption spectrum and hence a better harvesting of sunlight would be anticipated. It is also well-known that ruthenium(II) complexes are one of the best photosensitizing dyes used in dye-sensitized solar cells to date, in which the Grätzel-type cell owes much success to this work using these dyes (Grätzel et al., Nature, 1991, 353, 737; M. Grätzel, Nature, 2001, 414, 338; Ardo et al., Chem. Soc. Rev., 2009, 38, 115; Vougioukalakis et al., Coord. Chem. Rev., 2011, 255, 2602). The use of simple mononuclear ruthenium(II) bis(aryleneethynylene) complexes for BHJ devices is, however, unprecedented.

Accordingly, a preferred embodiment of the present invention relates to a ruthenium-containing complex for use in BHJ solar cells having a structure of Formula (I):

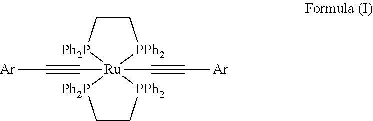

Wherein Ar is selected from a group consisting of at least one benzothiadiazole group, one or no triphenylamine group, at least one thiophene group and a mixture thereof.

Specifically, Ar is of the following structure:

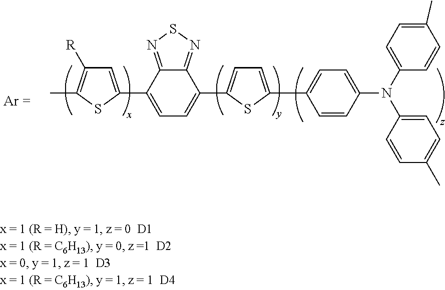

The four possible structures of the Ar group result in four ruthenium-containing complexes (D1, D2, D3 and D4) of Formula (I), which are further illustrated as follows:

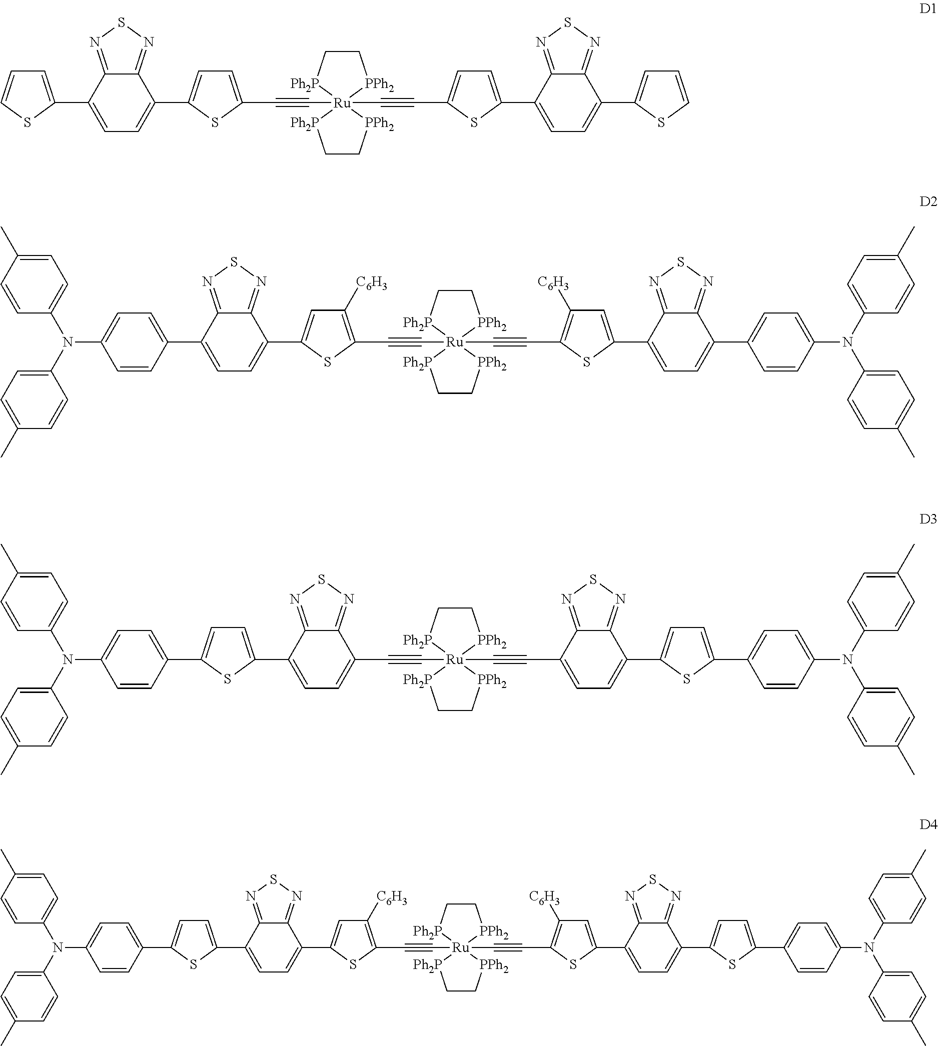

These ruthenium(II)-bis(aryleneethynylene) complexes (D1, D2, D3 and D4) consist of benzothiadiazole as the electron acceptor and triphenylamine and/or thiophene as the electron donor. The incorporation of a ruthenium metal center in a conjugated backbone and the presence of D-A structure in these complexes offer them with relatively low bandgaps and broad absorption profiles, which allow them to serve as suitable candidates for fabricating BHJ solar cells.

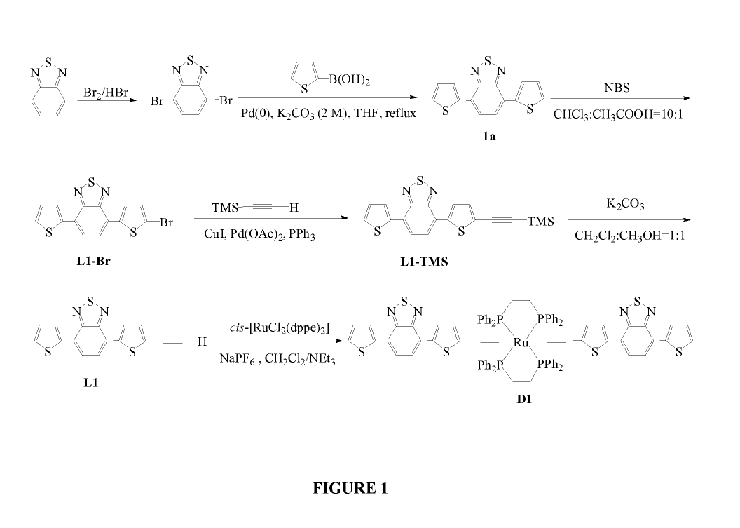

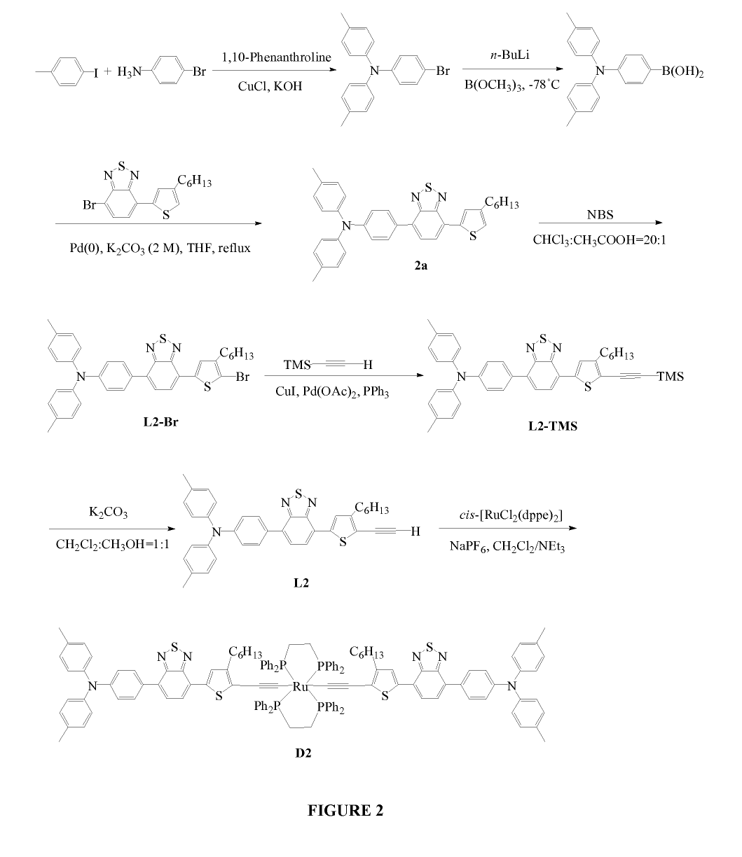

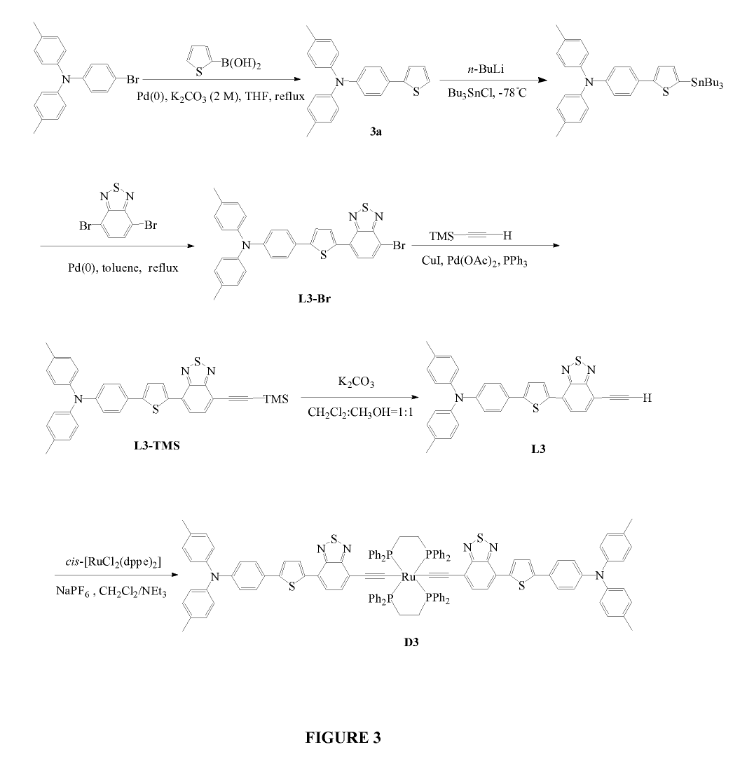

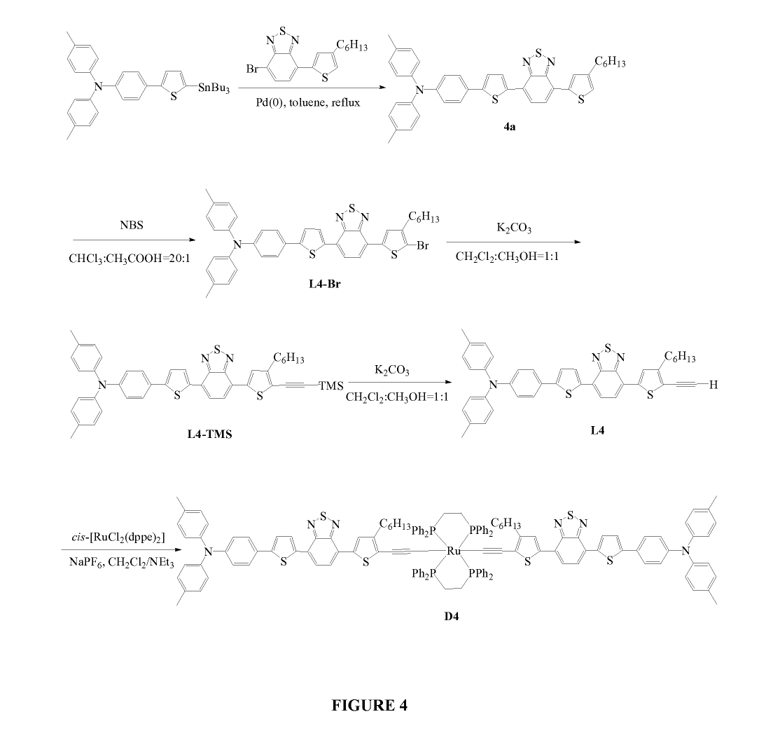

The approaches for preparing these ruthenium-containing complexes are shown in FIGS. 1-4. FIGS. 1-4 show the synthetic protocols for the aryleneethynylene ligands L1-L4 and the ruthenium(II) complexes D1-D4. The aryleneethynylene ligands L1 and L2 were prepared through the palladium-catalyzed Suzuki coupling reactions whereas L3 and L4 were prepared through the palladium-catalyzed Stille coupling reactions. The starting materials 2,1,3-benzothiadiazole and cis-[RuCl₂(dppe)₂] (dppe=bis(diphenylphosphino)ethane) can be obtained from commercial sources or synthesized by the methods known in the literature. For example, ligand L2 can be obtained from the Suzuki coupling of 4-bromo-7-(4-hexyl-2-thienyl)-2,1,3-benzothiadiazole with N,N-di-p-tolyl-4-aminophenylboronic acid followed by the Sonogashira coupling with trimethylsilylacetylene under the catalytic system of Pd(OAc)₂, CuI and PPh₃ (W.-Y. Wong et al., Chem. Eur. J. 2012, 18, 1502). cis-[RuCl₂(dppe)₂] was obtained by the reaction of RuCl₃.xH₂O with PPh₃ in refluxing methanol followed by reaction with dppe in acetone at room temperature for half an hour (M. A. Fox et al., J. Organomet. Chem., 2009, 694, 2350). The design rationale of L1-L4 is that each of them consists of benzothiadiazole as the electron acceptor and triphenylamine and/or thiophene as the electron donor, and one can readily modify the intramolecular charge transfer (ICT) strength of the donor-acceptor (D-A) component. A long hexyl chain on the thienyl ring can be used to enhance the solubility of D2 and D4. The ruthenium(II) complexes D1-D4 were obtained by reaction of cis-[RuCl₂(dppe)₂] with L1-L4 at room temperature in the presence of a catalytic amount of NaPF₆. Purification of the reaction mixture by flash column chromatography furnished the compounds as air-stable solids in high purity and moderate yields. All the ruthenium(H) complexes were fully characterized by NMR spectroscopy and FAB or MALDI-TOF mass spectrometry and shown to have well-defined structures.

The photophysical properties of these ruthenium(H) complexes D1-D4 were investigated by UV-Vis and photoluminescence (PL) spectroscopies in dichloromethane solutions at 293 K. The photophysical data of D1-D4 are collated in Table 1. The compounds of the present invention generally display broad absorption profiles. In many embodiments, the absorption peak maxima of D1-D4 are red-shifted (63-143 nm) relative to their corresponding ligands (c.f. the lowest-energy absorption λ_{abs}=449, 482, 493 and 515 nm for L1, L2, L3 and L4, respectively). From D1-D4, an obvious red shift has occurred because of an increase in the conjugation chain length in the presence of triphenylamine as an electron-donating group in the structure. Accordingly, a better harvesting of solar light is anticipated.

In general, these compounds have reasonably good film-forming properties for evaluating their photovoltaic performance. As a proof-of-concept demonstration, organic BHJ solar cell devices comprising D1 was also prepared. BHJ devices with the configuration of indium tin oxide (ITO)/poly(3,4-ethylenedioxythiophene)-poly(styrenesulphonate) (PEDOT-PSS)/D1:PC₇₀BM (1:4, w/w)/aluminum (Al) were fabricated. Poly(3,4-ethylene-dioxythiophene)-poly(styrenesulphonate) (PEDOT-PSS) serves as the hole-collection electrode, whereas Al serves as the electron-collecting electrode. The active blend layer of D1:PC₇₀BM was spin-coated from o-dichlorobenzene solution.

Certain preferred embodiments of the present invention has been described in details (infra), but it will be understood that various variations and modifications can be effected within the scope of the invention. The following examples are presented for a further understanding of the embodiments of the present invention.

### Example 1

### Compound and Device Properties

Ruthenium(II)-containing bis(aryleneethynylene) complexes D1-D4 are synthesized, characterized and used as electron donor materials in BHJ solar cells. Representative data for the photophysical properties as well as the preliminary photovoltaic behavior of the compounds are illustrated in Tables 1-2. These ruthenium(II) complexes have low bandgaps of 1.70-1.83 eV (Table 1). The incorporation of electron-accepting benzothiadiazole group and electron-donating triphenylamine and/or thiophene groups to the molecular skeleton to form D-A structures are found to red-shift the absorption peak and hence narrow the bandgap. So, a stronger ability in the harvesting of solar light can be achieved. To demonstrate the potential of these ruthenium(II)-bis(aryleneethynylene) molecular species as electron donor materials in solution-processed photovoltaic applications, BHJ devices were fabricated using PC₇₀BM as the electron acceptor. The hole-collection electrode consisted of indium tin oxide (ITO) with a spin-coated poly(3,4-ethylenedioxythiophene)-poly(styrenesulphonate) (PEDOT-PSS) layer, whereas Al served as the electron-collecting electrode. The active layers were prepared by spin-coating D1 and PC₇₀BM in o-dichlorobenzene with a weight ratio of 1:4. The open-circuit voltage (V_{oc}), short-circuit current density (J_{sc}), fill factor (FF), and the PCEs of these devices are summarized in Table 2.

TABLE 1
Photophysical Data of D1-D4 in CH₂Cl₂ at 298 K

| | Absorption | Emission | Optical bandgap |
|---|---|---|---|
| | λ_{abs}/nm (ε/10⁴ M⁻¹ cm⁻¹) | λₑₘ/nm | (eV) |
| D1 | 381 (2.52), 592 (2.28) | 591 | 1.83 |
| D2 | 311 (3.51), 387 (2.09), 581 (2.03) | 731 | 1.79 |
| D3 | 308 (1.31), 393 (1.63), 602 (1.27) | 678 | 1.80 |
| D4 | 306 (1.78), 382 (2.24), 578 (1.46) | 736 | 1.70 |

TABLE 2
Preliminary Photovoltaic Data of the BHJ Devices Based on D1

| | | Film | | | | |
|---|---|---|---|---|---|---|
| | Donor/ | thickness | | J_{sc} | | |
| Donor | PC₇₀BM | (nm) | V_{oc} (V) | (mA/cm²) | FF | PCE (%) |
| D1 | 1:4 | 65 | 0.51 | 4.24 | 0.31 | 0.66 |
| | | 85 | 0.52 | 3.88 | 0.29 | 0.58 |

### Example 2

### Synthesis of D1

Under a N₂ atmosphere, ligand L1 (100 mg, 0.19 mmol) and cis-[RuCl₂(dppe)₂] (92 mg, 0.095 mmol) were added to a mixture of triethylamine (Et₃N) and dichloromethane (CH₂Cl₂) (1:1, v/v) in the presence of a catalytic amount of sodium hexafluorophosphate (NaPF₆) (3.4 mg, 0.02 mmol, 10 mol %). The reaction mixture was stirred at room temperature overnight. The solvent was then removed under reduced pressure to obtain the crude product, which was purified by chromatography over a silica column using n-hexane/CH₂Cl₂ (1:1, v/v) as eluent to afford a pure sample of D1 as a dark blue solid (86.1 mg, yield: 45%). ¹H NMR (CDCl₃, 400 MHz, 6/ppm): 8.11 (m, 4H, Ar), 7.99 (d, J=8.0 Hz, 2H, Ar), 7.75 (d, J=8.0 Hz, 2H, Ar), 7.50-7.45 (m, 16H, PPh₂), 7.45 (m, 2H, Ar), 7.25-7.23 (m, 8H, PPh₂), 7.22 (m, 2H, Ar), 7.09-7.05 (m, 16H, PPh₂), 6.39 (m, 2H, Ar), 2.66 (m, 8H, dppe-CH₂); ³¹P NMR (CDCl₃, 162 Hz, δ/ppm): 52.82; IR (KBr): 2036 cm⁻¹ (w, ν(C≡C)); MALDI-TOF MS: m/z 1544.7 [M]⁺.

### Example 3

### Synthesis of D2

Ligand L2 (150 mg, 0.25 mmol) and cis-[RuCl₂(dppe)₂] (116 mg, 0.12 mmol) were added to a mixture of Et₃N and CH₂Cl₂ (1:1, v/v) in the presence of a catalytic amount of NaPF₆ (4.2 mg, 0.025 mmol, 10 mol %) under a N₂ atmosphere. The reaction mixture was stirred at room temperature overnight. The solvent was then removed to obtain the crude product, which was purified by chromatography over a silica column using n-hexane/CH₂Cl₂ (1:1, v/v) as eluent to afford D2 as a purple solid (85.2 mg, yield: 34%). ¹H NMR (CDCl₃, 400 MHz, δ/ppm): 8.02 (s, 2H, Ar), 7.89-7.86 (m, 4H, Ar), 7.69-7.67 (m, 2H, Ar), 7.50 (m, 16H, PPh₂), 7.19-7.15 (m, 12H, Ar), 7.11-7.09 (m, 18H, Ar), 7.06-6.99 (m, 16H, PPh₂), 2.77 (m, 8H, dppe-CH₂), 2.34 (s, 12H, Me), 2.09-2.07 (m, 4H, alkyl), 1.55-1.12 (m, 18H, alkyl), 0.85-0.82 (m, 4H, alkyl); ³¹P NMR (CDCl₃, 162 Hz, δ/ppm): 52.64; IR (KBr): 2026 cm⁻¹ (w, ν(C≡C)); MALDI-TOF MS: m/z 2091.7 [M]⁺.

### Example 4

### Synthesis of D3

To the solution of ligand L3 (120 mg, 0.24 mmol) and cis-[RuCl₂(dppe)₂] (106 mg, 0.11 mmol) in Et₃N/CH₂Cl₂ mixture (v/v=1:1) was added a catalytic amount of NaPF₆ (4.0 mg, 0.024 mmol, 10 mol %) under a N₂ atmosphere. After stirring the mixture at room temperature overnight, the solvent of the reacted mixture was removed and the crude product was obtained, which was then purified by chromatography over a silica column using n-hexane/CH₂Cl₂ (v/v=1:1) as eluent to afford D3 as a purple solid (91.0 mg, yield: 43%). ¹H NMR (CDCl₃, 400 MHz, δ/ppm) 8.07 (m, 2H, Ar), 7.63-7.61 (m, 2H, Ar), 7.56-7.54 (m, 16H, PPh₂), 7.32 (m, 2H, Ar), 7.11-7.04 (m, 32H, Ar), 6.84-6.80 (m, 16H, PPh₂), 6.42-6.40 (m, 2H, Ar), 2.99 (m, 8H, dppe-CH₂), 2.35 (s, 12H, Me); ³¹P NMR (CDCl₃, 162 Hz, δ/ppm): 53.73; IR (KBr): 2032 cm⁻¹ (w, ν(C≡C)); MALDI-TOF MS: m/z 1924.6 [M]⁺.

### Example 5

### Synthesis of D4

Ligand L4 (95 mg, 0.14 mmol) and cis-[RuCl₂(dppe)₂] (66 mg, 0.068 mmol) were dissolved in a Et₃N/CH₂Cl₂ mixture (v/v=1:1), and NaPF₆ (2.4 mg, 0.014 mmol, 10 mol %) was added as a catalyst. Then, the mixture was stirred under N₂ at room temperature overnight. After evaporation of the solvent under reduced pressure, the resulting solid was purified by column chromatography on silica gel using n-hexane:CH₂Cl₂=1:1 (v/v) as eluent to afford D4 as a purple solid (56.9 mg, yield: 37%). ¹H NMR (CDCl₃, 400 MHz, δ/ppm): 8.11 (m, 2H, Ar), 8.03 (s, 2H, Ar), 7.87-7.85 (m, 2H, Ar), 7.71-7.69 (m, 2H, Ar), 7.55-7.53 (m, 6H, Ar), 7.50-7.48 (m, 16H, PPh₂), 7.32 (m, 2H, Ar), 7.19-7.16 (m, 8H, Ar), 7.11-7.09 (m, 12H, Ar), 7.06-6.99 (m, 22H, Ar), 2.99-2.78 (m, 8H, dppe-CH₂), 2.34 (s, 12H, Me), 2.10-2.06 (m, 4H, alkyl), 1.46-1.13 (m, 18H, alkyl), 0.85-0.82 (m, 4H, alkyl); ³¹P NMR (CDCl₃, 162 Hz, δ/ppm): 52.63; IR (KBr): 2024 cm⁻¹ (w, ν(C≡C)), MALDI-TOF MS: m/z 2254.9 [M]⁺.

### Example 6

### Photophysical Properties

The absorption and photoluminescence data of D1-D4 are listed in Table 1. D1-D4 show two or three broad and structureless absorption bands in the range of 300-700 nm. From D1 to D4, an obvious red shift in absorption wavelength occurred because of an increase in the conjugation chain length. Also, a red-shifted peak from that of D1 is shown at around 602 nm for D3 which has a triphenylamine as an electron-donating group in the structure. As shown in FIG. 5, for D1-D4, the absorption bands at the short wavelengths centered within 306-393 nm are ascribed to the π-π* transitions of the aryleneethynylene segment. The low-energy broad absorption bands centered within 578-602 nm can be assigned to the ICT transition from the triphenylamine and/or thiophene donating groups to the benzothiadiazole accepting unit. As compared to the free ethynyl ligands, there is a red shift (ca. 63-143 nm) in the long-wavelength absorption peak for their corresponding ruthenium(II) compounds. It is commonly seen that a stronger electron-donating strength can result in a higher degree of electronic delocalization and hence a stronger ICT in the molecular donor materials. The bandgaps of D1-D4 are in the range of 1.70-1.83 eV (Table 1). As compared to D1, each of the compounds D2-D4 shows a significant red-shift of the optical bandgap, which is due to the stronger electron-donating ability of triphenylamine unit in these small molecules. In the cases of D2 and D3, which have almost the same π-conjugated length of the molecular structure, D3 shows a similar bandgap as D2. Because of the longest conjugation length, D4 gave the lowest bandgap of 1.70 eV in the series.

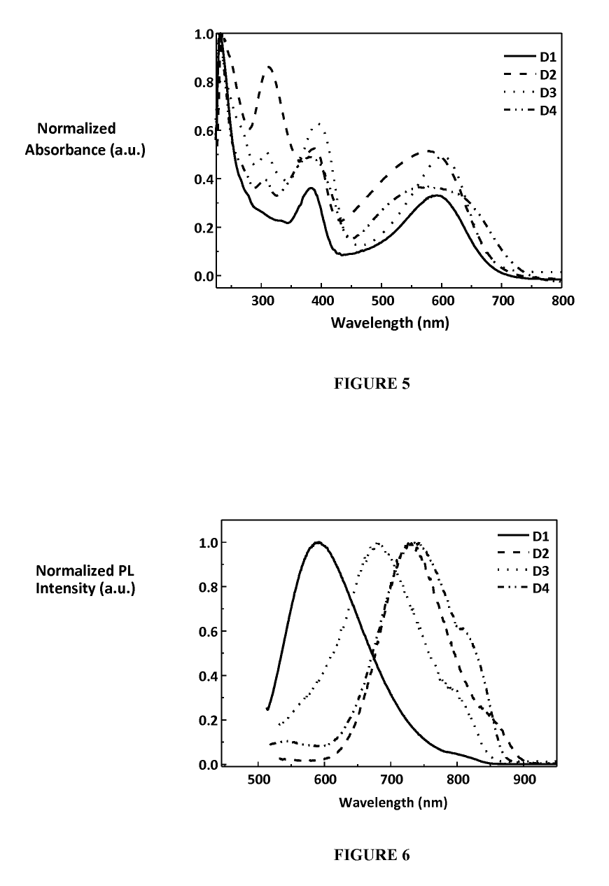

All of the ruthenium(II) bis(aryleneethynylene) compounds and their corresponding ligands are photoluminescent in dichloromethane at 298 K. The photoluminescence spectra show roughly a similar order as the absorption bandgaps. As shown in FIG. 6, D1-D4 display red fluorescence peaks with the emission maxima at 591, 731, 678, and 736 nm, respectively. Triplet emissions were not observed at room temperature, which are in accordance with the energy gap law for low bandgap metal-containing ethynylenic conjugated polymers and monomers (Wilson et al. J. Am. Chem. Soc. 2001, 123, 9412.).

### Example 7

### Photovoltaic Data of BHJ Solar Cells Based on D1

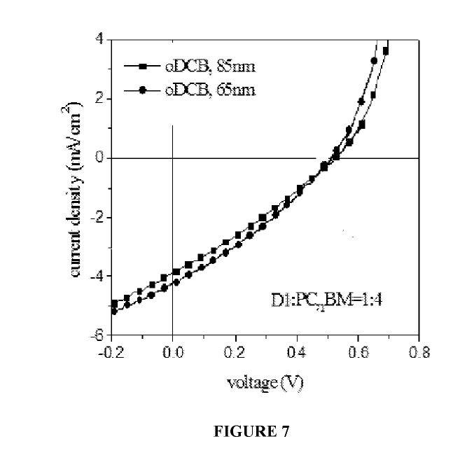

In order to test in a preliminary way this new class of ruthenium-containing bis(aryleneethynylene) complexes as photoactive donor materials for BHJ solar cells, we have prepared and tested solar cell devices based on blends of D1 and PC₇₀BM, fabricated with the structure of ITO/PEDOT-PSS/D1:PC₇₀BM (1:4, w/w)/Al by solution processing technique. The V_{oc}, J_{sc}, FF and PCE of these devices are summarized in Table 2 and FIG. 7. It was shown that both thicker and thinner active layers resulted in lower PCEs, because a very thin active layer reduces the absorption of the irradiated light, and, on the other hand, a very thick active layer slows down the charge transport in the active layer of these devices. A moderate PCE value of 0.66% was obtained using D1. Although the PCEs values are not very high, it is anticipated that they could be improved through modifications in the device fabrication (e.g. blend ratio, film thickness, solvent, etc.).

1. A ruthenium-containing complex having structure of Formula (I): 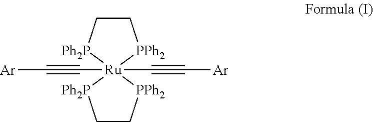
wherein Ar is selected from a group consisting of at least one benzothiadiazole group, one or no triphenylamine group, at least one thiophene group and a mixture thereof.

2. The ruthenium-containing complex according to claim 1, wherein

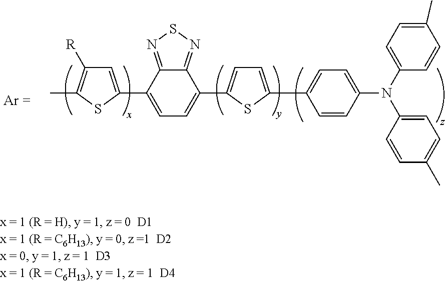

3. A method of preparing the ruthenium-containing complex of claim 1, comprising steps of:
(a) providing a ligand with structure of Ar—C≡CH;
(b) providing a ruthenium-containing compound;
(c) reacting the ligand with the ruthenium-containing compound in a solvent to form a crude product;
(d) purifying the crude product.

4. The method according to claim 3, wherein the ruthenium-containing compound comprises cis-[RuCl₂(bis(diphenylphosphino)ethane)₂].

5. The method according to claim 3, wherein the solvent comprises triethylamine, dichloromethane or a mixture thereof.

6. The method according to claim 3, wherein the reacting step is conducted in the presence of a catalyst.

7. The method according to claim 6, wherein the catalyst comprises sodium hexafluorophosphate.

8. The method according to claim 3, wherein the purifying step is conducted by column chromatography.

9. A bulk heterojunction solar cell device, comprising:
a hole-collection electrode;
an electron-collection electrode;
an active layer disposed between the hole-collection and electron-collection electrodes;
wherein the active layer comprises the ruthenium-containing complex of claim 1.

10. The bulk heterojunction solar cell device of claim 9, wherein the active layer further comprises a fullerene derivative.

11. The bulk heterojunction solar cell device of claim 10, wherein the fullerene derivative comprises PC₇₀BM.

12. The bulk heterojunction solar cell device of claim 11, wherein the ruthenium-containing complex and the PC₇₀BM is in a weight ratio of 1:4.

13. The bulk heterojunction solar cell device of claim 9, wherein the hole-collection electrode comprises indium tin oxide with a spin-coated poly(3,4-ethylene-dioxythiophene)/poly(styrenesulphonate) layer.

14. The bulk heterojunction solar cell device of claim 9, wherein the electron-collecting electrode comprises aluminum.
